(19) United States
(12) Patent Application Publication
(10) Pub. No.: US 2007/0212904 A1
(43) Pub. Date: Sep. 13, 2007

(54) Busbar connection module

(75) Inventor: Alex Buttner, Rodental (DE)

Correspondence Address: SUGHRUE MION, PLLC, 2100 PENNSYLVANIA AVENUE, N.W., SUITE 800, WASHINGTON, DC, 20037, US

(73) Assignee: WOHNER GMBH & CO. KG

(21) Appl. No.: 11/518,947

(22) Filed: Sep. 12, 2006

(30) Foreign Application Priority Data
Sep. 14, 2005 (DE) 102005043878.4

(51) Int. Cl. H05K 1/00

(52) U.S. Cl. 439/76.2

(57) ABSTRACT

The invention relates to a busbar connection module comprising a housing and a predetermined number of clamping devices arranged in the housing for receiving and fastening exposed line ends, comprising feet projecting on the underside of the clamping devices for fastening to busbars, the clamping devices being arranged in succession in a plane and being constructed without screws.

The invention relates to a busbar connection module comprising a housing and a predetermined number of clamping devices arranged in the housing for receiving and fastening electric lines of exposed cable ends according to the preamble of claim 1.

A known busbar connection module which is formed with three poles and consists of a housing is described in FIG. 1, wherein a number of clamping devices matched to the number of poles is provided. FIG. 1 is a plan view of the connection module, which consists of a housing 1 comprising three clamping devices 2, 3, 4 in the embodiment illustrated. Partitions 5, 6 are located between the clamping devices 2, 3, 4. The lines are indicated by 7, 8, 9 in FIG. 1.

FIG. 2 is a side view of a terminal, as designated by 2 to 4, in conjunction with FIG. 1. The terminal 2 shown in FIG. 2 consists of a metal body 10, which is bent substantially in a U-shape, and two mutually parallel wall portions 10a, between which is arranged a contact 11, fixed on the housing side, as well as a mating contact 12 which can be adjusted relative to the metal body 10 and can be adjusted in height relative to the contact 11 by screwing means 13 for the purpose of clamping the exposed end of one of the cables 7 to 9. The end of the metal body 10, which has been bent approximately into an L-shape or is mouth-like, is located at the lower end of the module and is closed laterally by insulating walls, the lower foot portion, provided with teeth 10c, of the metal body engaging under one of the busbars, not shown in the figure, in such a way that the mouth-like opening receives a busbar. The metal body 10 is enclosed by insulating feet which are formed on the underside of the housing and surround the body 10 on three sides.

A connection module of this type contains line connection terminals with terminal plates. The conductor connection terminals consist here of metal holding bodies with wire protection clips and clamping screws. The connection module is fastened to the busbars in such a way that the lines or cables, which are generally guided downwards from the housing, do not impede one another. Depending on the cross-section of the lines, the terminals are placed with lateral spacing on the busbars. The connection terminals are commercially available for cable cross-sections of 16 to 300 mm. The busbar connection module has connection plates made of insulating material, such as plastics material, which contain the conductor connection terminals. As described above, the connection terminals or clamping devices are already arranged in an insulating manner relative to one another with corresponding spacing, so the lines are held on the adjacent phase bars in an insulating manner.

A connection module of this type has the disadvantage that, owing to the side-by-side arrangement and the longitudinally offset arrangement of the clamping devices 2, 3, 4, a relatively large amount of space is required, i.e. the connection module has a complex structure overall. The further disadvantage is that the line ends have to be clamped by screwing using a tool to actuate the screw 13 or, if a replacement is required, the screw means 13 have to be released.

The object of the invention is to improve a busbar connection module of the type mentioned at the outset in such a way that a small amount of space is required and the exposed line ends can be installed simply and rapidly.

In accordance with the invention this object is achieved by the features recited in claim 1.

The invention provides a busbar connection module, which is constructed without screws and in which the clamping devices for receiving the exposed line ends are provided in succession in a plane according to the invention. A screwless connection module of this type can be used for cables with a maximum cross-section of 16 mm².

According to the invention, a connection module of this type may have a width of about 1 cm and is formed with multiple poles. For the purpose of connecting the exposed line ends, it is ensured here in a simple and reliable manner that the exposed line ends are guided from above through a through-opening downwards into the module and are fixed automatically by a spring clamp provided in the module. The exposed line ends are in electrical contact here with the respective spring contacts provided in the module, on the one hand, and a tongue of a retaining spring, on the other hand. When the line ends have to be removed from the module, this can also be effected in a simple and rapid manner, in that the end of a screwdriver or another tool is guided through a separate through-opening to pivot one end of the retaining spring out of the locking position relative to the line end.

In a preferred embodiment of the connection module according to the invention, the walls defining the receiving chambers are moulded or sprayed on a side wall of the housing, while the other side wall can be fixed by latching means to the basic housing. In this manner, the spring contacts and retaining springs can be easily and rapidly fitted for installation in the housing. In the busbar connection module according to the invention, the exit of the line, i.e. the exit of the connection cable, can be upward or downward.

The housing is also provided with a cover which can be opened selectively by upward or downward pivoting. As a result, the cover does not have to be removed during the wiring process. In the open position, the cover is inevitably held and does not hinder installation of the connection cables.

A latching element is also integrated in the housing and ensures a secure fit of the busbar connection module on all common bar widths of a busbar system. A combifoot which points downwards and is moulded onto the housing allows application to busbars with a thickness of 5 or 10 mm, for example.

The busbar connection module according to the invention is provided for lines or cables with a maximum wire thickness of 16 mm².

Preferred embodiments of the busbar connection module according to the invention will be described hereinafter with the aid of the drawings to describe further features.

### IN THE DRAWINGS

FIG. 1 is a plan view of a known busbar connection module,

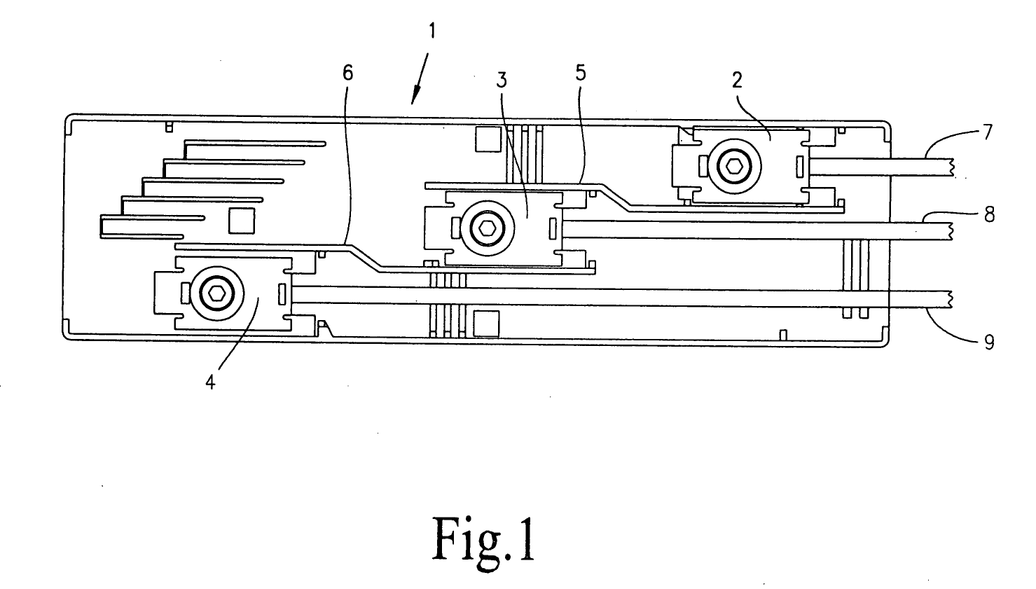

FIG. 2 is the view of a known clamping device for use in the busbar connection module according to FIG. 1,

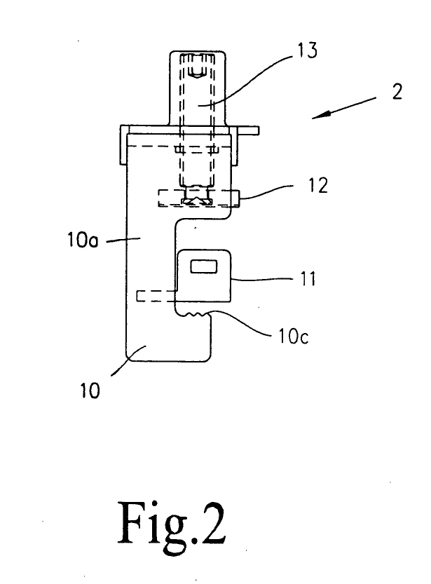

FIG. 3 is a perspective side view of the connection module according to the invention,

FIG. 4a is a view corresponding to FIG. 3 with the side wall removed for detailed illustration of the receiving chambers and the spring contacts and retaining springs used,

FIG. 4b is an enlarged partial view from FIG. 4a,

FIG. 5 is an exploded view of the connection module to illustrate the individual parts,

FIG. 6a is a schematic perspective view of a connection module for describing the cover and

FIG. 6b is a view which has been modified relative to FIG. 6a to illustrate the mode of operation of the cover.

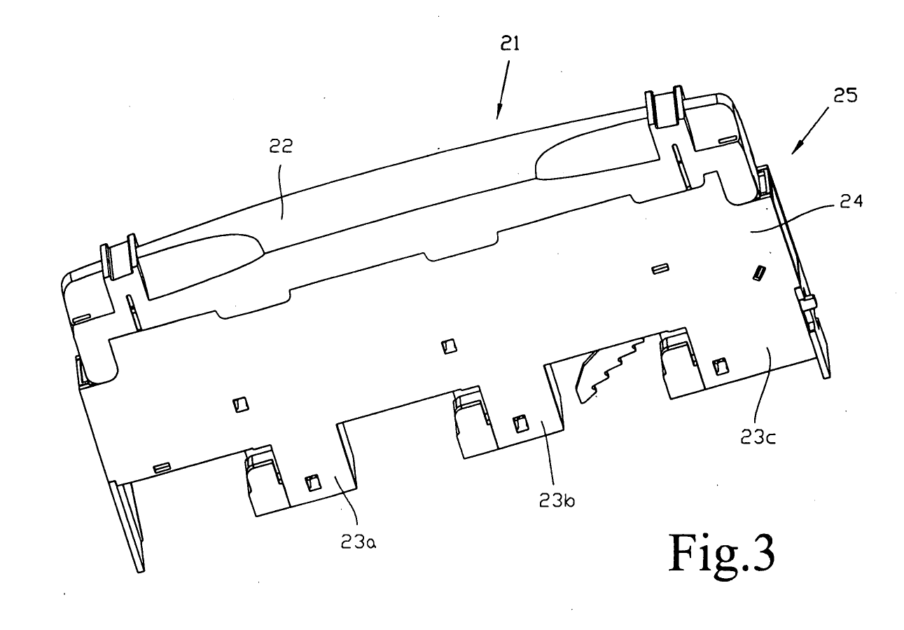

The busbar connection module according to the invention, hereinafter in brief called a connection module, will be described hereinafter. FIG. 3 is a perspective view of the connection module which consists of a housing 21 and a cover 22. Foot portions 23a, 23b, 23c, leading downwards, are provided on the housing 22. The housing 21 and the foot portions 23a, 23b consist of a plastics material or an insulating material. The foot portions 23a to 23c are used for application to busbars, not shown in detail, and contain the electrical contacts of the connection module, as will be further described below.

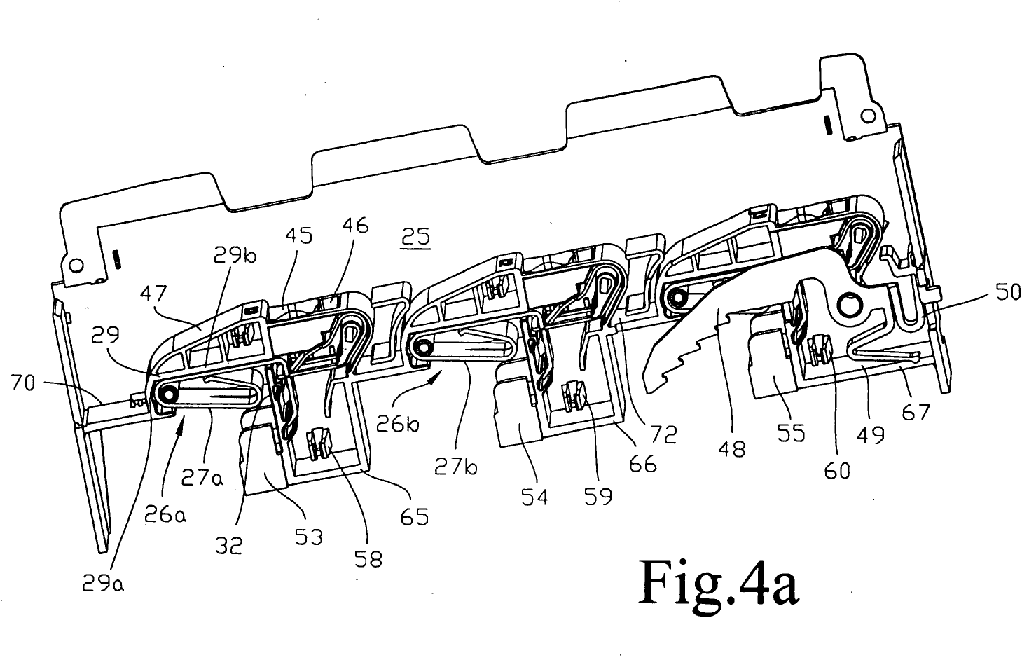

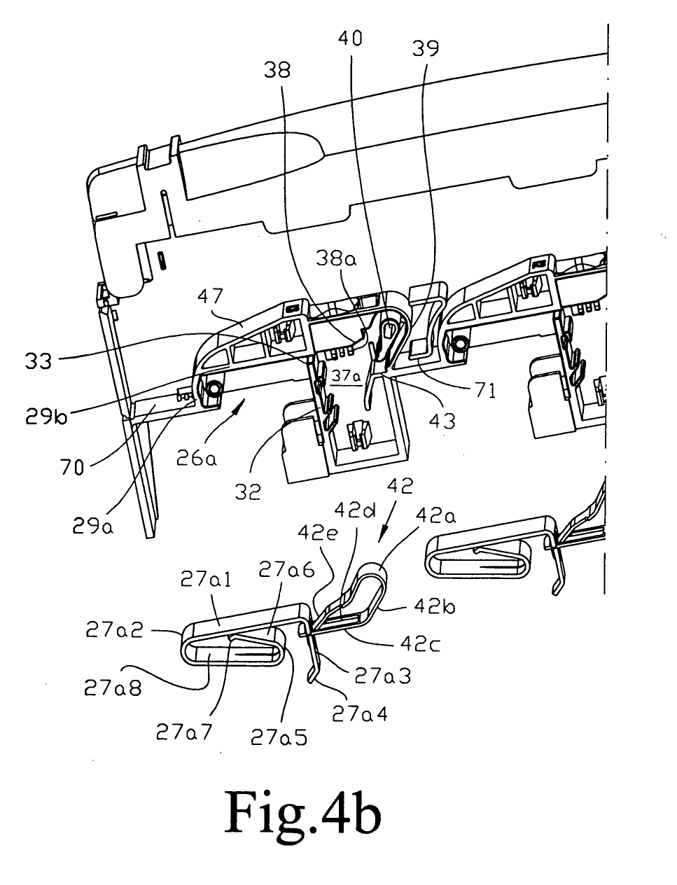

Referring to FIGS. 3 and 4, the connection module has two mutually parallel side walls 24, 25, the side wall 24 being removed in FIG. 4a to illustrate the structure of the connection module. In the embodiment shown, the side wall 24 can be fastened relative to the side wall 25 by latching devices, as will be described.

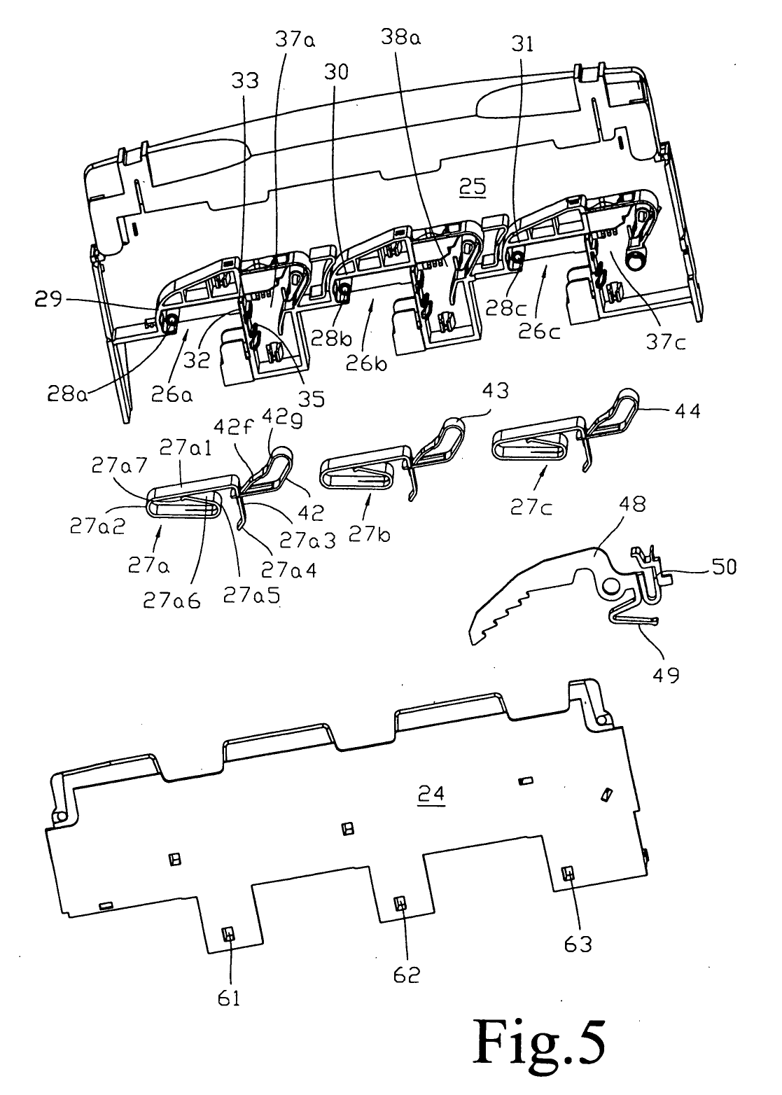

In accordance with FIG. 4a, the connection module contains a respective receiving chamber 26a, 26b, 26c in the case of a configuration of the connection module with three poles for receiving a respective spring contact, which is designated by 27a, 27b, 27c in FIG. 4a. Each receiving chamber 26a, 26b, 26c is open downwards, so each spring contact 27a, 27b, 27c can be contacted by the busbars extending in the region of the foot portions 23a, 23b, 23c. Located inside the downwardly open receiving chambers 26a to 26c is a bearing pin 28a, 28b, 28c which is spaced apart from the adjacent wall 29, 30, 31, so the respective spring contact can be guided round over this bearing pin, as can be seen from FIGS. 4a and 5.

The walls 29, 30, 31 defining the receiving chambers 26a, 26b, 26c have a predetermined course, which is described in more detail hereinafter with reference to the wall 29. The wall 29 (FIG. 4a) consists of a portion 29a which extends substantially vertically, optionally in a slightly curved manner, and a region 29b which extends substantially horizontally and substantially preferably straight, the walls 29a, 29b, which can also be called webs, being used as lateral support walls of the respective spring contacts 27a. The substantially horizontally extending wall or web portion 29b is used to support the portion 27a₁, extending parallel thereto, of the spring contact 27a (see FIG. 5). The bearing device 28a is surrounded by a bent spring portion 27a₂, which acts as a spring joint. Finally, each receiving chamber 26a, 26b, 26c is limited by a side web or a side wall 32, which extends vertically in the embodiment shown and keeps an opening slot 23 free relative to the wall portion 29b, through which slot the extension of the spring contact portion 27a₁ passes, as can be seen from FIG. 4a, before a substantially vertically downwardly extending spring contact portion 27a₃ adjoins the portion 27a₁, the spring contact portion extending downwards to the right of the side wall 32 and substantially parallel thereto, optionally spaced apart therefrom in FIGS. 4a and 5.

In the embodiment shown the end of the spring contact portion 27a₃ is preferably bent slightly inwards, i.e. in the direction of the bent portion 27a₂ and rests in a bearing slot 35, which is formed in each foot portion 23a, 23b, 23c laterally relative to the wall 32 to allow reliable latching of the portion 27a relative to the housing. In this manner each spring contact with its leg 27a₃ is arranged rigidly relative to the housing, i.e. the receiving or holding slot 35 and the leg 27a₃ cannot move away from its position when being slipped onto the respective busbar.

As FIGS. 4 and 5 also show, the spring contact has a further bent section 27a₅, adjoined by a bent-back spring tongue 27a₆, which rests or can rest with its slightly bent-back end 27a₇ on the underside of the spring contact portion 27a₁ when the connection module is placed or slipped onto the busbar. In non-operative mode, on the other hand, the spring end 27a₇ may maintain a slight spacing from the contact portion 27a₁.

Located between the bend regions 27a₂ and 27a₅ of the spring contact is a portion, which extends substantially straight and is designated 27a₈. The detailed course of a preferably used spring contact 27 will be apparent from the enlarged view of FIG. 4b, a gap of a few millimetres being present between the portion 27a₁ and 27a₇, when it is not applied to busbars.

Apart from the receiving chamber 26a, a second receiving chamber 37a, 37b, 37c is provided in each case, as shown in FIG. 5. This second receiving chamber is described in more detail with reference to the chamber 37a and referring to FIG. 4a, 4b and FIG. 5. The receiving chamber 37a is limited on the left-hand side in FIG. 4b by the side wall 32 and by webs or walls 38, 39. In particular, reference is made to FIG. 4b. Located between the webs or walls 38, 39 is a bearing device 40 in the form of a web or a rib, over which a spring clamp 42 is placed. A leaf or spring clamp 42, 43, 44 is provided for each spring contact. The slightly inclined wall 39, in the embodiment shown, passes into a substantially horizontally extending support wall 43, which projects from the wall 39 over a predetermined distance in the direction of the wall 32. The bearing device 40 maintains a predetermined spacing from the wall 39, so the spring clamp 42 can be inserted on the bearing device 40 and partially resting on the wall 39, 42 into the chamber 37a. The spring clamp 42 is correspondingly formed and, according to FIG. 4b, has a bent spacing [sic] (42a), which comes to rest substantially on the bearing device 40, furthermore a portion 42b emanating therefrom and extending substantially straight, a portion 42c emanating therefrom, which in turn contains a longitudinal slot 42d with a width, which corresponds approximately to the tongue 42e, receiving the spring clamp end located inside the slot 42d. The spring clamp portion 42c therefore receives the spring contact portion 27a₃, as can be seen, and at the same time the spring clamp end portion 42e, the spring clamp end portion 42e being pivotal about the bearing device 40 in the clockwise direction in FIG. 4b in the manner still to be illustrated, when a line end is inserted.

As will be apparent from FIG. 4a, the spring clamp portion 42c is approximately horizontal and approximately perpendicular to the spring contact portion 27a due to the support wall 43, as the spring clamp portion 42c rests on the support wall 43 and is thereby held in this horizontal position. It can also be seen that the spring portion 42b rests on the wall 39. Located between the spring clamp end portion 42e and the bent portion 42a are two further portions 42f and 42g which are slightly inclined relative to one another and are shown, for the sake of clarity, only in FIG. 5. In order to limit the position of the spring clamps, in particular the position of the spring clamp portion 42g, a projection 38a is formed on the limiting wall 38 on the housing side and limits the movement of the spring clamp portion 42g.

As will be apparent from FIG. 4a, each spring clamp 42, 43, 44 acts with the tongue portion designated 42e in FIG. 4b in the direction of the spring contact portion 27a. As the spring clamp portion 42e can be pivoted about the bearing 40 in the clockwise direction, the tongue portion 42e can therefore be moved away from the spring contact portion 27a₃ if a line is guided from above through an opening still to be described. The exposed line portion thus comes to rest between the spring contact portion 27a and the spring clamp portion 42e and is fixed by the spring clamp portion 42e in such a way that it is locked or clamped against being pulled out in the direction of the upper side of the housing.

As will be apparent from the foregoing description, each spring contact 27 defines a doubly sprung contact, namely, on the one hand, in the region of the spring joint on the bearing device 28a, 28b, 28c, and on the other hand, by the bent portion 27a₅, which acts in a resilient manner, when the tongue portion 27a₇ comes to rest on the portion 27a₁.

As can be seen from FIG. 4a, a through-opening 45, through which a line end is guided with its exposed end, is located above each receiving chamber 37a, 37b, 37c, in order to pivot this spring leg in the clockwise direction as described after impinging on the spring clamp 42 in the region of the portions 42e and 42f, allowing the insertion of the exposed line end up to a desired depth and in parallel with the spring contact portion 27a. Apart from the through-opening 45, a through-opening 46, which is independent thereof, is formed, which allows access to the spring clamp portion 42g by means of a screwdriver or a similar tool with the aim of pivoting the spring clamp portion 42f in the clockwise direction to release a line end from engagement between the spring contact portion 27a₃ and the spring clamp end portion 42e.

The present statements show that the connection module according to the invention thus allows screwless fastening of line ends, which are inserted in a simple and rapid manner through the respective through-opening 45 into the receiving chamber 37a or 37b or 37c and are fixed automatically by the action between the spring contact 27a etc. and spring clamp 42a etc., and are secured against being pushed out. However, the line ends can be released again in a simple and rapid manner, in that the spring clamp 42a etc. is actuated in the manner described above by means of a screwdriver or another suitable tool, to release the cable ends.

Although, in the above-described embodiment, the through-openings 45 and 46 are directed substantially vertically, these may also be inclined or provided in another manner in order to allow line ends to be pushed in or pulled out, even in a direction which is different from the vertical direction.

The number of clamping devices for the connection lines is oriented in the embodiment shown toward two line connections, i.e. for a connection module with three poles. The number of poles can be increased or reduced as required. The number of clamping devices is to be increased or reduced accordingly.

It is important for the fastening and clamping devices for the connection terminals to be provided side by side in a respective plane, thus ensuring an extraordinarily narrow configuration of the connection module. The screwless connection module according to the invention therefore ensures secure, vibration-resistant and gas-tight conductor clamping of the connection line. The above-described courses of the walls and webs also ensure the necessary length between poles, so creepage and air paths can be adapted to necessary desired requirements.

For this purpose, a wall portion 47 emanates obliquely upwards from the wall 29 shown in FIG. 4a, so the walls 47 and 29 produce an approximately triangular shape and therefore comparatively large spacing between the introduction portion 45 for the connection line and the spring contact 26a below the wall 29b.

In the embodiment shown, a latching element 48 is also provided (FIG. 4a), which is biased in the anti-clockwise direction by an angled foot. This ensures that, once the connection module has been applied to the busbar system, there is a secure fit relative to the busbar system. The portions 49 and 50 thus generate a spring action. In particular, reference is made to FIG. 4a.

As will be apparent from the drawing, the receiving chambers 37a, 37b, 37c are provided with laterally projecting supports forming the foot portions, which engage under the busbars when applied to the busbar system, as is known per se. These combifeet or supports are designated 53, 54, 55 in FIG. 4a.

The side wall 24 shown in FIG. 5 is preferably provided releasably relative to the side wall 25 to fasten the side wall 24 to the side wall 25. Latching means 58, 59, 60 projecting from the side wall 25, preferably in the region of the second receiving chambers 37a, 37b, 37c, are provided which, after application of the side wall 24, engage in corresponding openings 61, 62, 63 (FIG. 5) of the side wall 24 and hold the side wall 24 with spacing from the side wall 25. The side wall 24 thus comes to rest on the front edges of the walls 29, 47 etc. and of the walls 65, 66, 67 defining front edges of the foot portions (FIG. 4a) which, together with the already described wall 32, form the second receiving chamber with an approximately rectangular shape in the embodiment shown.

In the embodiment shown, the webs or walls 29, 29a, 32, 65, 66, 67 etc. are preferably moulded on the wall 25 and are produced therewith in one operation. After introduction of the spring contacts and spring clamps, the wall 24 can finally be applied. As will be apparent from FIG. 4 and FIG. 5 with the exception of the passages 45, 46, a separation is provided between the upper side and the underside of the connection module, for which purpose transverse wall sections 70, 71, 72 extending in the axial direction of the connection module are provided.

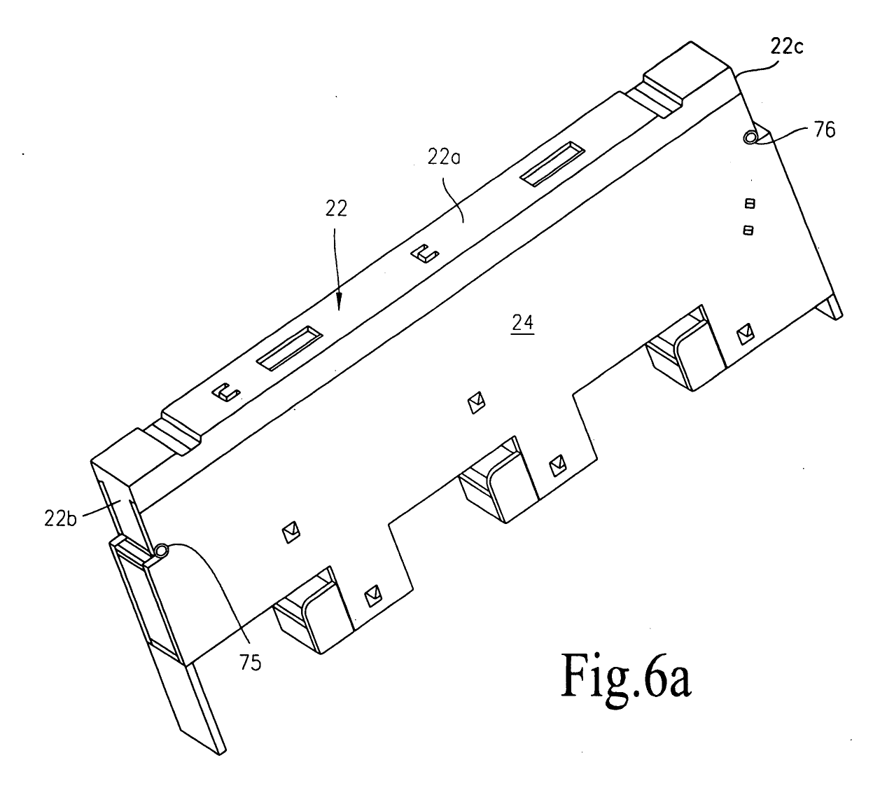

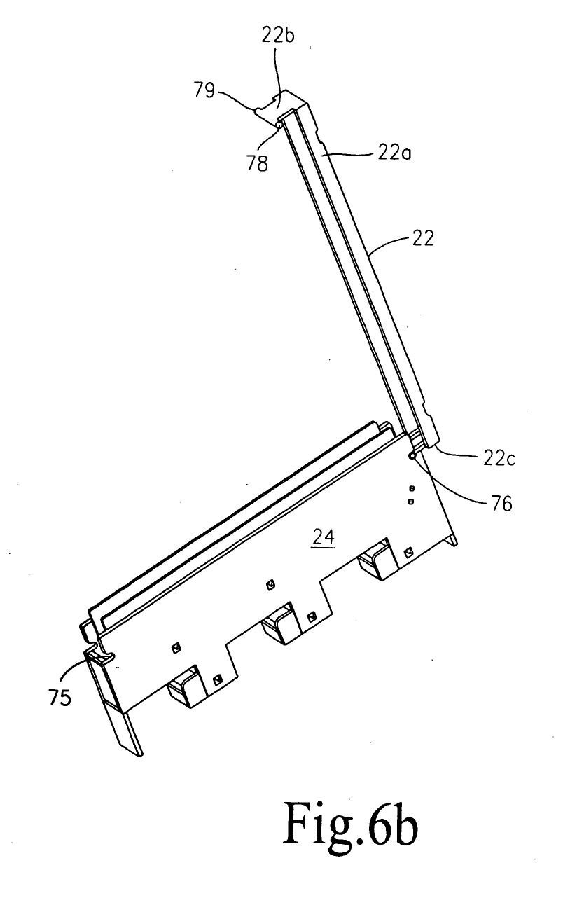

The lines or line ends inserted in the connection module according to the invention are preferably guided out laterally from the connection module. To close the connection module according to the invention, a preferably pivotal lid is provided thereon, which is briefly described with reference to FIGS. 6a and 6b. The closing lid has a substantially U-shaped form with a transverse leg 22a and two lateral short legs 22b, 22c leading from the transverse leg 22a. To receive the closing lid 22, arcuate recesses 75, 76 are formed, for example, in the two mutually parallel walls 24, 25, which recesses can be brought into engagement with, for example, pin-like projections 78, 79 on the lid 22 in that these pin-like projections 78, 99 can be “snapped into” the semicircular recesses 75, 76. It is therefore possible to keep the lid 22 pivotally mounted on one side, whereas, on the other side, it can be removed at the same time. The lid 22 is thus pivotally held, according to FIG. 6b, on the connection module, when it is released relative to the latching openings on the opposing side. Instead of semicircular recesses 75, 76, corresponding slots can be provided to allow a degree of displaceability of the pin-shaped bearing devices 78, 79.

As will be apparent from FIGS. 6a and 6b, the cover plates 22 are formed by pin-shaped joints 78, 79, which can be latched in corresponding joint openings 75, 76 in the two side walls 24, 25. These pin-shaped joints 78, 79 extend perpendicularly to the axis of the cover plate 22 in this embodiment.

1. Busbar connection module comprising a housing and a predetermined number of clamping devices arranged in the housing for receiving and fastening exposed line ends, comprising feet projecting on the underside of the clamping devices for fastening to busbars,
wherein the clamping devices are arranged in succession in a plane and are constructed without screws,
said housing comprising first receiving chambers for spring contacts, which are arranged side by side in a plane,
wherein the first receiving chambers are fixed by walls or webs, which are moulded or sprayed onto at least one of the side walls of the housing,
further comprising a second receiving chamber, which is provided, in each case, adjacent to each of the first receiving chambers for receiving, in each case, one of the clamping devices.

2. Busbar connection module according to claim 1,
wherein each clamping device is formed by a spring clamp.

3. Busbar connection module according to claim 1,
wherein each spring clamping device has a slotted spring tongue or a spring tongue, with an opening, in which a portion of the respective spring contact and an adjustable tongue of the spring clamp engage.

4. Busbar connection module according claim 1,
wherein each first receiving chamber comprises a bearing device holding the associated spring contacts in the first receiving chamber.

5. Busbar connection module according to claim 1,
wherein the first and second receiving chamber are divided by a partition which establishes a through-slot, through which a leg of the respective spring contacts is guided.

6. Busbar connection module according to claim 1,
wherein each second receiving chamber comprises a bearing device for each associated clamping device.

7. Busbar connection module according to claim 1,
wherein the second receiving chamber comprises a substantially horizontally extending support wall for supporting a leg of the respective clamping device.

8. Busbar connection module according claim 1,
said second receiving chamber each comprising a laterally terminating side wall which at least partially surrounds the respective clamping device.

9. Busbar connection module according to claim 1,
said housing further comprising a through-opening being arranged between each spring contact and the associated clamping device to guide through a line end in the direction of a movable spring tongue of the associated clamping device.

10. Busbar connection module according claim 1,
wherein said housing further comprises a through-opening which is provided to guide through a tool such as a screwdriver in the direction of the clamping device to pivot a leg of the respective clamping device to release a line connection end.

11. Busbar connection module according to claim 1,
wherein said housing is provided with a latching means for fastening a side wall which can be applied to the housing.

12. Busbar connection module comprising a housing and a predetermined number of clamping devices arranged in the housing for receiving and fastening exposed line ends, comprising feet projecting on the underside of the clamping devices for fastening to busbars,
wherein the clamping devices are arranged in succession in a plane and are constructed without screws,
said housing comprising first receiving chambers for spring contacts, which are arranged side by side in a plane,
wherein the first receiving chambers are fixed by walls or webs, which are moulded or sprayed onto at least one of the side walls of the housing,
further comprising a second receiving chamber, which is provided, in each case, adjacent to each of the first receiving chambers for receiving, in each case, one of the clamping devices,
wherein said housing is provided with a latching means for fastening a side wall which can be applied to the housing,
wherein said side wall comprises latching openings associated with further latching means arranged in said housing.

13. Busbar connection module according to claim 12,
wherein said further latching means are formed in the second receiving chamber.

14. Busbar connection module according claim 1,
wherein said housing comprises parallel side walls and a cover plate,
said side walls having openings,
wherein said cover plate is provided with joints, which can be latched into the openings of the side walls.

15. Busbar connection module comprising a housing and a predetermined number of clamping devices arranged in the housing for receiving and fastening exposed line ends, comprising feet projecting on the underside of the clamping devices for fastening to busbars,
wherein the clamping devices are arranged in succession in a plane and are constructed without screws,
said housing comprising first receiving chambers for spring contacts, which are arranged side by side in a plane,
wherein the first receiving chambers are fixed by walls or webs, which are moulded or sprayed onto at least one of the side walls of the housing,
further comprising a second receiving chamber, which is provided, in each case, adjacent to each of the first receiving chambers for receiving, in each case, one of the clamping devices,
wherein said housing comprises parallel side walls and a cover plate,
said side walls having openings,
wherein said cover is provided with joints, which can be latched into the opening of the side walls,
wherein the joints formed on the cover plate are formed in the shape of pins or pegs and extend perpendicularly to the axis of the cover plate.
